(19) United States
(12) Patent Application Publication
(10) Pub. No.: US 2023/0017856 A1
(43) Pub. Date: Jan. 19, 2023

(54) RESIN SHEET AND MANUFACTURING METHOD THEREOF

(71) Applicant: DENKA COMPANY LIMITED, Tokyo (JP)

(72) Inventors: Yusuke SASAKI, Saitama-shi (JP); Kenji MIYATA, Machida-shi (JP); Michiharu NAKASHIMA, Machida-shi (JP)

(73) Assignee: DENKA COMPANY LIMITED, Tokyo (JP)

(21) Appl. No.: 17/784,959

(22) PCT Filed: Dec. 11, 2020
(86) PCT No.: PCT/JP2020/046334

§ 371 Date: Jun. 13, 2022

(30) Foreign Application Priority Data
Dec. 17, 2019 (JP) 2019-227265

(51) Int. Cl. C08J 5/18; C08K 3/38; C01B 21/064; H01L 23/36

(52) U.S. Cl. CPC C08J 5/18; C08K 3/38; C01B 21/064; H01L 23/36

(57) ABSTRACT

A method of producing a resin sheet, including: mixing blocky boron nitride particles A, blocky boron nitride particles B, and a resin composition, and molding the resin composition to a sheet form and pressurizing the sheet form resin composition, the boron nitride primary particles a having a length in a shorter direction of 0.7 μm or less, the boron nitride primary particles b having a length in a shorter direction of 1 μm or more, the blocky boron nitride particles A having an average particle diameter of 30 μm or more, the blocky boron nitride particles B having an average particle diameter that is smaller than the average particle diameter of the blocky boron nitride particles A, the compressive strengths ratio of the blocky boron nitride particles A to the blocky boron nitride particles B being 1.2 or more. Thus, the thermal conductivity of a resin sheet can be enhanced.

### TECHNICAL FIELD

The present invention relates to a resin sheet and a method of producing the same.

### BACKGROUND ART

Electronic components, such as a power device, a transistor, a thyristor, and a CPU, involve problems in efficiently radiating heat generated in use. For solving the problems, the increase of the thermal conductivity of an insulating layer of a printed circuit board for mounting an electronic component, and the attachment of an electronic component or a printed circuit board to a heatsink via an electrically insulating thermal interface material have been practiced. As the insulating layer and the thermal interface material, for example, a resin sheet containing a resin and a thermal conductive filler (i.e., a thermal conductive sheet) has been used.

As the thermal conductive filler, boron nitride particles having characteristics, such as a high thermal conductivity, a high insulation capability, and a low relative permeability, are receiving attention. For example, PTL 1 describes a thermal conductive sheet containing a fluorine resin and a thermal conductive filler containing boron nitride particles, having a thermal resistance under pressure of 0.05 MPa of 0.90° C./W or less.

### CITATION LIST

### Patent Literature

PTL 1: JP 2018-203857 A

### SUMMARY OF INVENTION

### Technical Problem

The importance of heat radiation is being increased associated with the increase of the speed and the integration degree of circuits inside an electronic component and the increase of the mounting density of electronic components on a printed circuit board in recent years. Accordingly, a resin sheet having a thermal conductivity that is higher than ever before is being demanded.

Under the circumstances, an object of the present invention is to enhance the thermal conductivity of a resin sheet.

### Solution to Problem

One aspect of the present invention is a method of producing a resin sheet, including: a step of mixing blocky boron nitride particles A including scaly boron nitride primary particles a aggregated, blocky boron nitride particles B including scaly boron nitride primary particles b aggregated, and a resin, so as to provide a resin composition, and a step of molding the resin composition to a sheet form and pressurizing the resin composition molded into a sheet form, the boron nitride primary particles a having a length in a shorter direction of 0.7 μm or less, the boron nitride primary particles b having a length in a shorter direction of 1 μm or more, the blocky boron nitride particles A having an average particle diameter of 30 μm or more, the blocky boron nitride particles B having an average particle diameter that is smaller than the average particle diameter of the blocky boron nitride particles A, the ratio of the compressive strength of the blocky boron nitride particles A to the compressive strength of the blocky boron nitride particles B being 1.2 or more.

In the aforementioned aspect, the ratio of the average particle diameter of the blocky boron nitride particles B to the average particle diameter of the blocky boron nitride particles A may be 0.7 or less. The content of the blocky boron nitride particles A in the resin composition may be 50 parts by volume or more per 100 parts by volume of the total amount of the blocky boron nitride particles A and the blocky boron nitride particles B. The content of the blocky boron nitride particles B in the resin composition may be 5 parts by volume or more per 100 parts by volume of the total amount of the blocky boron nitride particles A and the blocky boron nitride particles B.

Another aspect of the present invention is a resin sheet containing: a resin, blocky boron nitride particles A including scaly boron nitride primary particles a aggregated, and scaly boron nitride primary particles b that do not form blocky boron nitride particles, and are disposed in interspaces among the blocky boron nitride particles A, the boron nitride primary particles a having a length in a shorter direction of 0.7 μm or less, the boron nitride primary particles b having a length in a shorter direction of 1 μm or more, the blocky boron nitride particles A having an average particle diameter of 30 μm or more.

In the aforementioned aspect, the content of the blocky boron nitride particles A may be 50 parts by volume or more per 100 parts by volume of the total amount of the blocky boron nitride particles A and the boron nitride primary particles b. The content of the boron nitride primary particles b may be 5 parts by volume or more per 100 parts by volume of the total amount of the blocky boron nitride particles A and the boron nitride primary particles b.

In the aforementioned aspects, the resin sheet may be used as a heat radiation sheet.

### Advantageous Effects of Invention

According to the present invention, the thermal conductivity of a resin sheet can be enhanced.

### BRIEF DESCRIPTION OF DRAWINGS

FIG. 1 is an SEM image of the cross section of a resin sheet obtained in Example 1.

FIG. 2 is an SEM image of the cross section of a resin sheet obtained in Comparative Example 1.

### DESCRIPTION OF EMBODIMENTS

Embodiments of the present invention will be described in detail below.

One embodiment of the present invention is a method of producing a resin sheet, including: a step of mixing blocky boron nitride particles A, blocky boron nitride particles B, and a resin, so as to provide a resin composition (mixing step), and a step of molding the resin composition to a sheet form and pressurizing the resin composition molded into a sheet form (molding step).

The mixing step will be firstly described. The blocky boron nitride particles A include scaly boron nitride primary particles a aggregated. The boron nitride primary particles a have a length in the shorter direction of 0.7 μm or less. In the case where the length in the shorter direction of the boron nitride primary particles a is larger than 0.7 μm, there may be some cases where interspaces in the blocky boron nitride particles A may be increased to lower the thermal conductivity of the resin sheet. Furthermore, there may be some cases where the compressive strength of the blocky boron nitride particles A may be decreased. The blocky boron nitride particles B include scaly boron nitride primary particles b aggregated. The boron nitride primary particles b have a length in the shorter direction of 1 μm or more. In the case where the length in the shorter direction of the boron nitride primary particles b is less than 1 μm, there may be some cases where the compressive strength of the blocky boron nitride particles B is increased to make difficult to regulate the ratio of the compressive strength of the blocky boron nitride particles A to the compressive strength of the blocky boron nitride particles B to 1.2 or more. As described herein, the blocky boron nitride particles A and the blocky boron nitride particles B are particles that are different from each other.

The lengths in the shorter direction of the scaly boron nitride primary particles a and b each may also be referred to as the thickness of the scaly primary particles. The lengths in the shorter direction of the boron nitride primary particles a and b each may be measured as an average value of the lengths in the shorter direction of 50 primary particles on an SEM image of the primary particles. The lengths in a longer direction of the boron nitride primary particles a and b described later may also be measured in the same manner.

The length in the shorter direction of the boron nitride primary particles a is preferably 0.65 μm or less, and more preferably 0.60 μm or less, from the standpoint of the interspaces of the blocky boron nitride particles A and the compressive strength of the blocky boron nitride particles A. The lower limit value of the length in the shorter direction of the boron nitride primary particles a is not particularly limited, and is, for example, 0.3 μm or more, preferably 0.4 μm or more, and more preferably 0.5 μm or more. The length in the longer direction of the boron nitride primary particles a is not particularly limited, and for example, may be 1 μm or more, and may be 10 μm or less.

The length in the shorter direction of the boron nitride primary particles b is preferably 1.1 μm or more, more preferably 1.2 μm or more, and further preferably 1.3 μm or more, from the standpoint of the compressive strength of the blocky boron nitride particles B. The upper limit value of the length in the shorter direction of the boron nitride primary particles b is not particularly limited, and is, for example, 2 μm or less, preferably 1.8 μm or less, and more preferably 1.6 μm or less. The length in the longer direction of the boron nitride primary particles b is not particularly limited, and for example, may be 2.5 μm or more, and may be 15 μm or less.

The average particle diameter of the blocky boron nitride particles A is 30 μm or more from the standpoint of the reduction of the interfaces among the blocky boron nitride particles in the resin sheet for enhancing the thermal conductivity of the resin sheet, and is preferably 40 μm or more, more preferably 50 μm or more, further preferably 60 μm or more, and particularly preferably 70 μm or more, from the standpoint of the promotion of achievement of the same effect. The average particle diameter of the blocky boron nitride particles A may be, for example, 150 μm or less, 120 μm or less, or 100 μm or less.

The average particle diameter of the blocky boron nitride particles B is smaller than the average particle diameter of the blocky boron nitride particles A. According to the configuration, the blocky boron nitride particles B enter into the interspaces among the blocky boron nitride particles A, and thereby the filling rate of boron nitride in the resin sheet can be further increased to further enhance the thermal conductivity of the resin sheet. Specifically, the ratio of the average particle diameter of the blocky boron nitride particles B to the average particle diameter of the blocky boron nitride particles A (average particle diameter of blocky boron nitride particles B/average particle diameter of blocky boron nitride particles A) is preferably 0.7 or less, more preferably 0.65 or less, further preferably 0.6 or less, and particularly preferably 0.5 or less, from the standpoint of the further enhancement of the thermal conductivity of the resin sheet. The lower limit value of the ratio of the average particle diameters is not particularly limited, and may be, for example, 0.1 or more, 0.2 or more, or 0.25 or more. The average particle diameters of the blocky boron nitride particles A and B each mean the volume average particle diameter measured by the laser diffractive scattering method.

The average particle diameter of the blocky boron nitride particles B is preferably selected to satisfy the ratio of the average particle diameters described above. The average particle diameter of the blocky boron nitride particles B is, for example, 50 μm or less, and is preferably 40 μm or less, and more preferably 30 μm or less, from the standpoint of the further enhancement of the thermal conductivity of the resin sheet. The lower limit value of the average particle diameter of the blocky boron nitride particles B is not particularly limited, and may be, for example, 10 μm or more, 15 μm or more, or 20 μm or more.

The compressive strength of the blocky boron nitride particles A is larger than the compressive strength of the blocky boron nitride particles B. According to the configuration, pressure can be applied to the resin composition in the molding step described later in such a manner that only the aggregation of the boron nitride primary particles b in the blocky boron nitride particles B can be broken while retaining the aggregation of the boron nitride primary particles a in the blocky boron nitride particles A. The interspaces among the blocky boron nitride particles A can be filled up with the boron nitride primary particles b formed by breaking the aggregation of the blocky boron nitride particles B. Specifically, the ratio of the compressive strength of the blocky boron nitride particles A to the compressive strength of the blocky boron nitride particles B (compressive strength of blocky boron nitride particles A/compressive strength of blocky boron nitride particles B) is not particularly limited, as far as only the aggregation of the boron nitride primary particles b in the blocky boron nitride particles B can be favorably broken while retaining the aggregation of the boron nitride primary particles a in the blocky boron nitride particles A in the molding step described later, and for example, is 1.2 or more from the standpoint of the further enhancement of the thermal conductivity of the resin sheet, and is preferably 1.3 or more, more preferably 1.4 or more, further preferably 1.5 or more, and particularly preferably 1.6 or more, from the standpoint of the promotion of achievement of the same effect. The upper limit value of the ratio of the compressive strengths is not particularly limited, and may be, for example, 4 or less, 3 or less, or 2 or less.

The compressive strengths of the blocky boron nitride particles A and B each are a value that is measured according to JIS R1639-5:2007. The measurement apparatus used may be a micro compression tester (for example, “MCT-W500”, product name, produced by Shimadzu Corporation). The compressive strength (σ, unit: MPa) is calculated from the dimensionless number varying depending on the position in the particle (α=2.48, no unit), the compressive test force (P, unit: N), and the particle diameter (d, unit: μm) according to the expression σ=α×P/(π×d²).

The compressive strength of the blocky boron nitride particles A is preferably selected to satisfy the ratio of the compressive strengths described above. The compressive strength of the blocky boron nitride particles A is, for example, 4 MPa or more, and is preferably 5 MPa or more, and more preferably 6 MPa or more, from the standpoint of the more favorable retention of the aggregation of the boron nitride primary particles a in the blocky boron nitride particles A in the molding step described later. The upper limit value of the compressive strength of the blocky boron nitride particles A is not particularly limited, and may be, for example, 15 MPa or less, 12 MPa or less, or 10 MPa or less.

The compressive strength of the blocky boron nitride particles B is also preferably selected to satisfy the ratio of the compressive strengths described above. The compressive strength of the blocky boron nitride particles B is, for example, 8 MPa or less, and is preferably 7 MPa or less, and more preferably 6 MPa or less, from the standpoint of the more favorable breakage of the aggregation of the boron nitride primary particles b in the blocky boron nitride particles B in the molding step described later. The compressive strength of the blocky boron nitride particles B is not particularly limited, as far as the aggregation of the blocky boron nitride particles B is not broken in the mixing step described later, and may be, for example, 2 MPa or more, 3 MPa or more, or 4 MPa or more.

The content of the blocky boron nitride particles A in the resin composition is, for example, 25% by volume or more, preferably 30% by volume or more, and more preferably 35% by volume or more, based on the total volume of the resin composition, from the standpoint of the enhancement of the thermal conductivity of the resin sheet. The content of the blocky boron nitride particles A in the resin composition is, for example, 60% by volume or less, preferably 57.5% by volume or less, and more preferably 55% by volume or less, from the standpoint of the prevention of the occurrence of voids in the resin sheet.

The content of the blocky boron nitride particles A in the resin composition is preferably 50 parts by volume or more, more preferably 55 parts by volume or more, and further preferably 60 parts by volume or more, and is preferably 95 parts by volume or less, more preferably 90 parts by volume or less, further preferably 85 parts by volume or less, and particularly preferably 70 parts by volume or less, per 100 parts by volume of the total amount of the blocky boron nitride particles A and the blocky boron nitride particles B, for example, from the standpoint of the further enhancement of the filling rate of boron nitride in the resin sheet for further enhancing the thermal conductivity of the resin sheet.

The content of the blocky boron nitride particles B in the resin composition is, for example, 5% by volume or more, preferably 10% by volume or more, and more preferably 15% by volume or more, and is, for example, 25% by volume or less, preferably 22.5% by volume or less, and more preferably 20% by volume or less, based on the total volume of the resin composition, from the standpoint of the further enhancement of the filling rate of boron nitride in the resin sheet for further enhancing the thermal conductivity of the resin sheet.

The content of the blocky boron nitride particles B in the resin composition is preferably 5 parts by volume or more, more preferably 10 parts by volume or more, further preferably 15 parts by volume or more, and particularly preferably 30 parts by volume or more, and is preferably 50 parts by volume or less, more preferably 45 parts by volume or less, and further preferably 40 parts by volume or less, per 100 parts by volume of the total amount of the blocky boron nitride particles A and the blocky boron nitride particles B, for example, from the standpoint of the further enhancement of the filling rate of boron nitride in the resin sheet for further enhancing the thermal conductivity of the resin sheet.

Examples of the resin include an epoxy resin, a silicone resin, silicone rubber, an acrylic resin, a phenol resin, a melamine resin, a urea resin, an unsaturated polyester, a fluorine resin, a polyimide, a polyamideimide, a polyetherimide, a polybutylene terephthalate, a polyethylene terephthalate, a polyphenylene ether, a polyphenylene sulfide, a wholly aromatic polyester, a polysulfone, a liquid crystal polymer, a polyether sulfone, a polycarbonate, a maleimide-modified resin, an ABS (acrylonitrile-butadiene-styrene) resin, an AAS (acrylonitrile-acrylic rubber-styrene) resin, and an AES (acrylonitrile-ethylene propylene diene rubber-styrene) resin.

The content of the resin in the resin composition is, for example 40% by volume or more, preferably 42.5% by volume or more, and more preferably 45% by volume or more, from the standpoint of the enhancement of the thermal conductivity of the resin sheet, and is, for example, 60% by volume or less, preferably 57.5% by volume or less, and more preferably 55% by volume or less, from the standpoint of the prevention of the occurrence of voids in the resin sheet, all based on the total volume of the resin composition.

In the mixing step, an additional component may be further mixed in addition to the blocky boron nitride particles A, the blocky boron nitride particles B, and the resin. The additional component may be a curing agent. The curing agent may be selected depending on the kind of the resin. For example, in the case where the resin is an epoxy resin, examples of the curing agent include a phenol novolak compound, an acid anhydride, an amino compound, and an imidazole compound. The content of the curing agent may be, for example, 0.5 part by mass or more, 1 part by mass or more, 5 parts by mass or more, or 8 parts by mass or more, and may be, for example, 15 parts by mass or less, 12 parts by mass or less, or 10 parts by mass or less, per 100 parts by mass of the resin.

The molding step subsequent to the mixing step may include a step of coating the resin composition obtained in the mixing step (coating step), and a step of pressurizing the coated resin composition (pressurizing step). According to the procedure, the resin composition molded into a sheet form (i.e., the resin sheet) can be obtained.

In the coating step, the resin composition is coated on a substrate (for example, a polymer film, such as a PET film), for example, with a film applicator. The thickness of the coated resin composition may be, for example, 0.05 mm or more, 0.1 mm or more, or 0.5 mm or more, and may be, 2 mm or less, 1.5 mm or less, or 1.2 mm or less. In the coating step, the resin composition may be defoamed, for example, under reduced pressure, after coating the resin composition on the substrate.

In the pressurizing step, pressure is applied to the resin composition. The pressure is appropriately selected corresponding to the compressive strengths of the blocky boron nitride particles A and B, so that only the aggregation of the boron nitride primary particles b in the blocky boron nitride particles B is broken while retaining the aggregation of the boron nitride primary particles a in the blocky boron nitride particles A. The pressure may be, for example, 2 MPa or more, 3 MPa or more, or 4 MPa or more, and may be, 15 MPa or less, 14 MPa or less, or 13 MPa or less.

In the pressurizing step, the resin composition may be heated in application of pressure. The heating temperature may be, for example, 100° C. or more, 120° C. or more, or 150° C. or more, and may be, 250° C. or less, 230° C. or less, or 200° C. or less. According to the procedure, the resin composition (resin) can be semi-cured or completely cured.

The period of time of applying pressure (and heating depending on necessity) in the pressurizing step may be, for example, 10 minutes or more, 30 minutes or more, or 50 minutes or more, and may be, 6 hours or less, 4 hours or less, or 2 hours or less.

In the production method of a resin sheet described above, the blocky boron nitride particles A and the blocky boron nitride particles B, which are different from each other in the points including the average particle diameter and the compressive strength, are used, and the blocky boron nitride particles A have a larger average particle diameter and a larger compressive strength than the blocky boron nitride particles B. Accordingly, in molding the resin composition to a sheet form and pressurizing the resin composition molded into a sheet form in the molding step, the boron nitride primary particles a in the blocky boron nitride particles A having a larger compressive strength retain the aggregation, whereas the aggregation of the boron nitride primary particles b in the blocky boron nitride particles B having a smaller compressive strength can be broken. At this time, the boron nitride primary particles a have a length in the shorter direction of 0.7 μm or less, and thereby the number of the bonding sites among the boron nitride primary particles a is increased to facilitate the retention of the aggregation of the boron nitride primary particles a. As a result, in the resulting resin sheet, the blocky boron nitride particles A, which have a large average particle diameter and readily form thermal conduction channels (i.e., readily contribute to the enhancement of the thermal conductivity), exist, and simultaneously the boron nitride primary particles b formed through the breakage of the aggregation can exist in the interspaces among the blocky boron nitride particles A, which hardly conduct heat in the ordinary resin sheet. At this time, the boron nitride primary particles b have a length in the shorter direction of 1 μm or more, and thereby readily contribute to the enhancement of the thermal conductivity of the resin sheet. Consequently, the resin sheet obtained by the production method can effectively conduct heat over the entire resin sheet, as compared to the ordinary resin sheet having, for example, only blocky boron nitride particles existing in a resin, and thereby exhibits an excellent thermal conductivity.

Furthermore, the aggregation of the blocky boron nitride particles B is not broken before the pressurizing step, and therefore the blocky boron nitride particles B can be readily disposed at positions corresponding to the interspaces among the blocky boron nitride particles A. In the pressurizing step, the aggregation of the blocky boron nitride particles B, which have been disposed at the positions corresponding to the interspaces among the blocky boron nitride particles A, is broken, and thereby the interspaces among the blocky boron nitride particles A can be sufficiently filled up with the boron nitride primary particles b. According to the mechanism, the thermal conductivity of the resin sheet can be further enhanced. In the case where boron nitride primary particles b that are not aggregated are used instead of the blocky boron nitride particles B, on the other hand, there may be some cases where the moldability of the resin composition may be deteriorated, and the boron nitride primary particles b are hardly dispersed in the resin sheet. Accordingly, there may be some cases where the interspaces among the blocky boron nitride particles A may be insufficiently filled up with the boron nitride primary particles b, failing to enhance the thermal conductivity of the resin sheet.

Another embodiment of the present invention is a resin sheet containing: a resin, blocky boron nitride particles A including scaly boron nitride primary particles a aggregated, and scaly boron nitride primary particles b that do not form blocky boron nitride particles, and are disposed in interspaces among the blocky boron nitride particles A.

The details of the resin have been described above. The resin in the resin sheet may be, for example, in a semi-cured state (which may also be referred to as a B stage). The semi-cured state of the resin can be confirmed with, for example, a differential scanning calorimeter. The resin sheet can be into a completely cured state (which may also be referred to as a C stage) by further subjecting to a curing treatment.

The content of the resin in the resin sheet is, for example, 40% by volume or more, preferably 42.5% by volume or more, and more preferably 45% by volume or more, and is, for example, 60% by volume or less, preferably 57.5% by volume or less, and more preferably 55% by volume or less, based on the total volume of the resin sheet, from the standpoint of the prevention of occurrence of voids in the resin sheet.

The details of the boron nitride primary particles a, the blocky boron nitride particles A, and the boron nitride primary particles b have been described above.

The content of the blocky boron nitride particles A in the resin sheet is, for example, 25% by volume or more, preferably 30% by volume or more, and more preferably 35% by volume or more, based on the total volume of the resin sheet, from the standpoint of the enhancement of the thermal conductivity of the resin sheet. The content of the blocky boron nitride particles A in the resin sheet is, for example, 60% by volume or less, preferably 57.5% by volume or less, and more preferably 55% by volume or less, from the standpoint of the prevention of occurrence of voids in the resin sheet.

The content of the boron nitride primary particles b in the resin sheet is, for example, 5% by volume or more, preferably 10% by volume or more, and more preferably 15% by volume or more, and is, for example, 25% by volume or less, preferably 22.5% by volume or less, and more preferably 20% by volume or less, based on the total volume of the resin sheet, from the standpoint of the further enhancement of the filling rate of boron nitride in the resin sheet for further enhancing the thermal conductivity of the resin sheet.

The content of the blocky boron nitride particles A in the resin sheet is preferably 50 parts by volume or more, more preferably 55 parts by volume or more, and further preferably 60 parts by volume or more, and is preferably 95 parts by volume or less, more preferably 90 parts by volume or less, further preferably 85 parts by volume or less, and particularly preferably 70 parts by volume or less, per 100 parts by volume of the total amount of the blocky boron nitride particles A and the boron nitride primary particles b, for example, from the standpoint of the further enhancement of the filling rate of boron nitride in the resin sheet for further enhancing the thermal conductivity of the resin sheet.

The content of the boron nitride primary particles b in the resin sheet is preferably 5 parts by volume or more, more preferably 10 parts by volume or more, further preferably 15 parts by volume or more, and particularly preferably 30 parts by volume or more, and is preferably 50 parts by volume or less, more preferably 45 parts by volume or less, and further preferably 40 parts by volume or less, per 100 parts by volume of the total amount of the boron nitride primary particles A and the boron nitride primary particles b, for example, from the standpoint of the further enhancement of the filling rate of boron nitride in the resin sheet for further enhancing the thermal conductivity of the resin sheet.

The thickness of the resin sheet is preferably 0.05 mm or more, more preferably 0.1 mm or more, and further preferably 0.3 mm or more, for example, from the standpoint of the adhesiveness of the resin sheet, and is preferably 1.5 mm or less, more preferably 1 mm or less, and further preferably 0.7 mm or less, from the standpoint of the thermal conductivity of the resin sheet.

While the resin sheet includes the aggregated boron nitride primary particles a (i.e., the blocky boron nitride particles A) as described above, a part of the boron nitride primary particles a in the resin sheet may not form blocky boron nitride particles (i.e., may not be aggregated). The boron nitride primary particles a that do not form blocky boron nitride particles also fill up the interspaces among the blocky boron nitride particles A. The content of the boron nitride primary particles a that do not form blocky boron nitride particles (i.e., are not aggregated) in the resin sheet is, for example, 1% by volume or more, preferably 3% by volume or more, and more preferably 5% by volume or more, and is, for example, 20% by volume or less, preferably 15% by volume or less, and more preferably 10% by volume or less, based on the total volume of the resin sheet, from the standpoint of the further enhancement of the filling rate of boron nitride in the resin sheet for further enhancing the thermal conductivity of the resin sheet.

The resin sheet can be obtained, for example, by the production method described above. In this case, the boron nitride primary particles b that do not form blocky boron nitride particles in the resin sheet are a product formed as a result of the breakage of the aggregation of the boron nitride primary particles b in the blocky boron nitride particles B (i.e., a broken product of the blocky boron nitride particles B).

In the resin sheet described above, the blocky boron nitride particles A, which have an average particle diameter readily forming thermal conduction channels (i.e., readily contributing to the enhancement of the thermal conductivity), exist, and simultaneously the boron nitride primary particles b exist in the interspaces among the blocky boron nitride particles A, which hardly conduct heat in the ordinary resin sheet. Consequently, the resin sheet can effectively conduct heat over the entire resin sheet, as compared to the ordinary resin sheet having, for example, only blocky boron nitride particles existing in a resin, and thereby exhibits an excellent thermal conductivity. Therefore, the resin sheet can be favorably used, for example, as a heat radiation sheet (i.e., a heat radiation member).

### EXAMPLES

The present invention will be described more specifically with reference to examples below. However, the present invention is not limited to the examples below.

### Example 1

With a mixture of 100 parts by mass of a naphthalene type epoxy resin (“HP4032”, product name, produced by DIC Corporation) and 10 parts by mass of an imidazole compound (“2E4MZ-CN”, product name, produced by Shikoku Chemicals Corporation) as a curing agent, blocky boron nitride particles A1 (average particle diameter: 83.3 μm, compressive strength: 9 MPa) including scaly boron nitride primary particles a1 (length in shorter direction: 0.57 μm) aggregated, and blocky boron nitride particles B1 (average particle diameter: 25.8 μm, compressive strength: 5 MPa) including scaly boron nitride primary particles b1 (length in shorter direction: 1.40 μm) aggregated were mixed in an amount in total of 50% by volume, so as to provide a resin composition. At this time, the mixing ratio (volume ratio) of the blocky boron nitride particles A1 and the blocky boron nitride particles B1 was A1/B1=65/35.

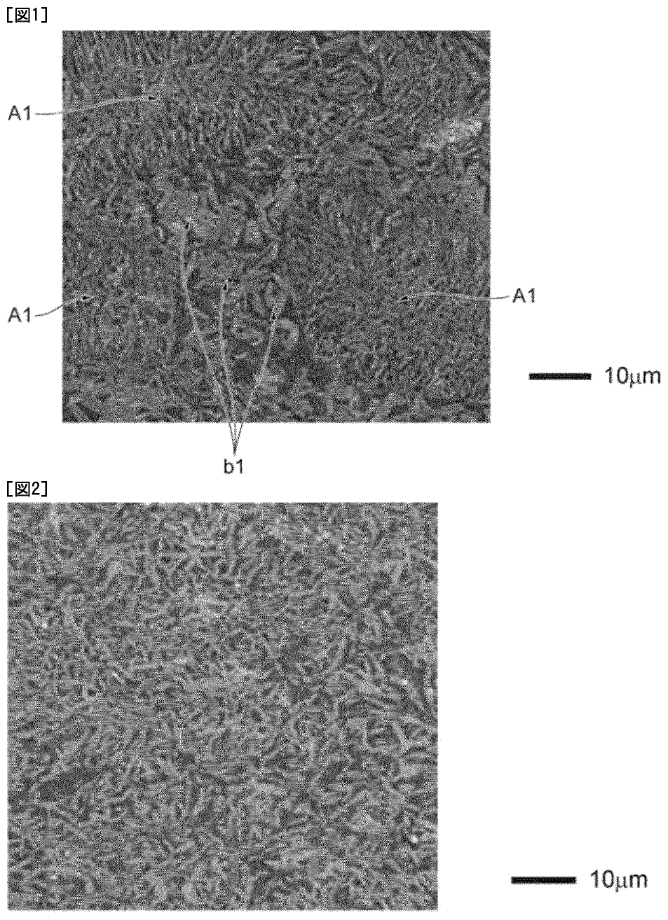

The resin composition was coated on a PET film to a thickness of 1 mm, and then defoamed under reduced pressure of 500 Pa for 10 minutes. Thereafter, the resin composition was heated and pressurized under condition of a temperature of 150° C. and 10 MPa for 60 minutes, so as to produce a resin sheet having a thickness of 0.5 mm. FIG. 1 shows the SEM image of the cross section of the resulting resin sheet.

### Comparative Example 1

A resin sheet was produced in the same manner as in Example 1 except that blocky boron nitride particles B2 (average particle diameter: 22.3 μm, compressive strength: 8 MPa) including scaly boron nitride primary particles b2 (length in shorter direction: 0.55 μm) aggregated were used instead of the blocky boron nitride particles B1. FIG. 2 shows the SEM image of the cross section of the resulting resin sheet.

TABLE 1

| Kind of blocky boron nitride particles | A1 | A2 | B1 | B2 | B3 | B4 | B5 |
|---|---|---|---|---|---|---|---|
| Length in shorter direction of boron nitride | 0.57 | 0.70 | 1.40 | 0.55 | 1.20 | 1.10 | 0.80 |
| primary particles (μm) | | | | | | | |
| Average particle diameter (μm) | 83.3 | 88.0 | 25.8 | 22.3 | 43.0 | 65.3 | 18.5 |
| Compressive strength (MPa) | 9 | 6 | 5 | 8 | 6 | 3 | 9 |

It is understood from FIG. 1 that the resin sheet of Example 1 contains the blocky boron nitride particles A1 including the boron nitride primary particles a1 aggregated, and the boron nitride primary particles b1 that do not form blocky boron nitride particles, and are disposed in interspaces among the blocky boron nitride particles A1. On the other hand, the resin sheet of Comparative Example 1 contains the blocky boron nitride particles A1 including the boron nitride primary particles a1 aggregated, and the blocky boron nitride particles B2 including the boron nitride primary particles b2 aggregated (i.e., both the blocky boron nitride particles retain the aggregated state).

### Examples 2 to 5

Resin sheets were produced in the same manner as in Example 1 except that the formulation of the blocky boron nitride particles was changed as shown in Table 2.

### Comparative Examples 2 and 3

Resin sheets were produced in the same manner as in Comparative Example 1 except that the formulation of the blocky boron nitride particles was changed as shown in Table 2.

### Example 6

A resin sheet was produced in the same manner as in Example 2 except that blocky boron nitride particles B3 (average particle diameter: 43.0 μm, compressive strength: 6 MPa) including scaly boron nitride primary particles b3 (length in shorter direction: 1.20 μm) aggregated were used instead of the blocky boron nitride particles B1.

### Example 7

A resin sheet was produced in the same manner as in Example 2 except that blocky boron nitride particles B4 (average particle diameter: 65.3 μm, compressive strength: 3 MPa) including scaly boron nitride primary particles b4 (length in shorter direction: 1.10 μm) aggregated were used instead of the blocky boron nitride particles B1.

### Example 4

A resin sheet was produced in the same manner as in Example 2 except that blocky boron nitride particles B4 (average particle diameter: 18.5 μm, compressive strength: 9 MPa) including scaly boron nitride primary particles b5 (length in shorter direction: 0.80 μm) aggregated were used instead of the blocky boron nitride particles B1.

### Comparative Example 5

A resin sheet was produced in the same manner as in Comparative Example 2 except that blocky boron nitride particles A2 (average particle diameter: 88.0 μm, compressive strength: 6 MPa) including scaly boron nitride primary particles a2 (length in shorter direction: 0.70 μm) aggregated were used instead of the blocky boron nitride particles A1.

### Measurement of Thermal Conductivity

A measurement specimen having a size of 10 mm×10 mm was cut out from each of the resin sheets of Examples and Comparative Examples, and measured for the thermal diffusion coefficient A (m²/sec) of the measurement specimen by the laser flash method using a xenon flash analyzer (“LFA 447 NanoFlash”, product name, produced by Netzsch GmbH & Co. KG). The measurement specimen was measured for the specific gravity B (kg/m³) by the Archimedes method. The measurement specimen was measured for the scanning heat capacity C (J/(kg K)) by using a differential specific calorimeter (DSC, “ThermoPlusEvo DSC 8230”, product name, produced by Rigaku Corporation). The thermal conductivity of each of the resin sheets was calculated from these measured values according to the expression, thermal conductivity H (W/(m·K))=A×B×C. The results are shown in Table 2.

TABLE 2

| | | Example | Example | Example | Example | Example | Example | Example |
|---|---|---|---|---|---|---|---|---|
| | | 1 | 2 | 3 | 4 | 5 | 6 | 7 |
| Formulation | A1 | 65 | 90 | 50 | 45 | 97 | 90 | 90 |
| of blocky | A2 | — | — | — | — | — | — | — |
| boron | B1 | 35 | 10 | 50 | 55 | 3 | — | — |
| nitride | B2 | — | — | — | — | — | — | — |
| particles | B3 | — | — | — | — | — | 10 | — |
| (part by | B4 | — | — | — | — | — | — | 10 |
| volume) | B5 | — | — | — | — | — | — | — |

| Thickness (mm) | 0.5 | | | | | | |
|---|---|---|---|---|---|---|---|
| Ratio | 0.31 | | | | | 0.52 | 0.78 |
| of average | | | | | | | |
| particle | | | | | | | |
| diameter | | | | | | | |
| Ratio of | 1.8 | | | | | 1.5 | 3 |
| compressive | | | | | | | |
| strength | | | | | | | |
| Thermal | 15.1 | 15.6 | 14.5 | 14.3 | 14.4 | 15.2 | 14.2 |
| conductivity | | | | | | | |
| (W/m · K) | | | | | | | |

| | | Comparative | Comparative | Comparative | Comparative | Comparative |
|---|---|---|---|---|---|---|
| | | Example 1 | Example 2 | Example 3 | Example 4 | Example 5 |
| Formulation | A1 | 65 | 90 | 50 | 90 | — |
| of blocky | A2 | — | — | — | — | 90 |
| boron | B1 | — | — | — | — | — |
| nitride | B2 | 35 | 10 | 50 | — | 10 |
| particles | B3 | — | — | — | — | — |
| (part by | B4 | — | — | — | — | — |
| volume) | B5 | — | — | — | 10 | — |

| Thickness (mm) | 0.5 | | | | |
|---|---|---|---|---|---|
| Ratio | 0.27 | | | 0.22 | 0.25 |
| of average | | | | | |
| particle | | | | | |
| diameter | | | | | |
| Ratio of | 1.125 | | | 1 | 0.75 |
| compressive | | | | | |
| strength | | | | | |
| Thermal | 11.9 | 14.0 | 11.0 | 13.0 | 10.0 |
| conductivity | | | | | |
| (W/m · K) | | | | | |

1. A method of producing a resin sheet, comprising:
a step of mixing blocky boron nitride particles A including scaly boron nitride primary particles a aggregated, blocky boron nitride particles B including scaly boron nitride primary particles b aggregated, and a resin, so as to provide a resin composition, and
a step of molding the resin composition to a sheet form and pressurizing the resin composition molded into a sheet form,
the boron nitride primary particles a having a length in a shorter direction of 0.7 μm or less,
the boron nitride primary particles b having a length in a shorter direction of 1 μm or more,
the blocky boron nitride particles A having an average particle diameter of 30 μm or more,
the blocky boron nitride particles B having an average particle diameter that is smaller than the average particle diameter of the blocky boron nitride particles A,
a ratio of a compressive strength of the blocky boron nitride particles A to a compressive strength of the blocky boron nitride particles B being 1.2 or more.

2. The production method according to claim 1, wherein a ratio of the average particle diameter of the blocky boron nitride particles B to the average particle diameter of the blocky boron nitride particles A is 0.7 or less.

3. The production method according to claim 1, wherein a content of the blocky boron nitride particles A in the resin composition is 50 parts by volume or more per 100 parts by volume of the total amount of the blocky boron nitride particles A and the blocky boron nitride particles B.

4. The production method according to claim 1, wherein a content of the blocky boron nitride particles B in the resin composition is 5 parts by volume or more per 100 parts by volume of the total amount of the blocky boron nitride particles A and the blocky boron nitride particles B.

5. The production method according to claim 1, wherein the resin sheet is used as a heat radiation sheet.

6. A resin sheet comprising:
a resin,
blocky boron nitride particles A including scaly boron nitride primary particles a aggregated, and
scaly boron nitride primary particles b that do not form blocky boron nitride particles, and are disposed in interspaces among the blocky boron nitride particles A,
the boron nitride primary particles a having a length in a shorter direction of 0.7 μm or less,
the boron nitride primary particles b having a length in a shorter direction of 1 μm or more,
the blocky boron nitride particles A having an average particle diameter of 30 μm or more.

7. The resin sheet according to claim 6, wherein a content of the blocky boron nitride particles A is 50 parts by volume or more per 100 parts by volume of the total amount of the blocky boron nitride particles A and the boron nitride primary particles b.

8. The resin sheet according to claim 6, wherein a content of the boron nitride primary particles b is 5 parts by volume or more per 100 parts by volume of the total amount of the blocky boron nitride particles A and the boron nitride primary particles b.

9. The resin sheet according to claim 6, wherein the resin sheet is used as a heat radiation sheet.
